(19) United States
(12) Patent Application Publication
(10) Pub. No.: US 2024/0186337 A1
(43) Pub. Date: Jun. 6, 2024

(54) DISPLAY PANEL

(71) Applicant: TCL CHINA STAR OPTOELECTRONICS TECHNOLOGY CO., LTD., Shenzhen, Guangdong (CN)

(72) Inventor: Yanling Chen, Shenzhen, Guangdong (CN)

(73) Assignee: TCL CHINA STAR OPTOELECTRONICS TECHNOLOGY CO., LTD., Shenzhen, Guangdong (CN)

(21) Appl. No.: 17/759,857

(22) PCT Filed: Jul. 26, 2022
(86) PCT No.: PCT/CN2022/107766

§ 371 Date: Jul. 30, 2022

(30) Foreign Application Priority Data
Jul. 14, 2022 (CN) 202210834424.2

(51) Int. Cl. H01L 27/12; G02F 1/1362; G02F 1/1368

(52) U.S. Cl. CPC H01L 27/1251; G02F 1/136209; G02F 1/13685

(57) ABSTRACT

A display panel is disclosed. A thin film transistor in a non-display area is provided with a protruding structure, and a source and drain electrode layer is disposed on the protruding structure. A source electrode and a drain electrode of the source and drain electrode layer both cover a first surface, a first side wall, and a second side wall of the protruding structure. A channel width of the thin film transistor is increased, and a ratio of the channel width to a channel length of the thin film transistor is increased. Therefore, a current of the thin film transistor is increased, a charging rate of the thin film transistor is improved, and a display performance of a display panel is improved.

### FIELD OF INVENTION

The present disclosure relates to the field of display technologies, and more particularly, to a display panel.

### BACKGROUND OF INVENTION

Liquid crystal displays (LCDs) have many advantages, such as thin body, power saving, and no radiation, and have been widely used. For example, they are used as LCD TVs, mobile phones, personal digital assistants (PDAs), digital cameras, computer screens, notebook computer screens, etc., and have been dominant in the field of flat panel display. Its working principle is that under the action of electric fields, an alignment direction of liquid crystal molecules is changed to change (modulate) a light transmittance of an external light source, completing an electro-optical conversion. Then different activation of R, G, B three primary color signals are used to complete color reproduction in time domain and space domain by red, green, and blue three primary color filter films.

Wherein, a gate driver on array (GOA) technique is to fabricate a gate scanning drive circuit of thin film transistors (TFTs) on an array substrate to realize a driving method of progressive scanning, which has advantages of reducing production costs and realizing a narrow bezel design of panels. The GOA technique can reduce soldering of external integrated circuits (ICs), so it can effectively reduce the production costs and increase production capacity. At the same time, it makes display panels more suitable for making display products with narrow bezels.

Technical problem: at present, large-size and high-definition liquid crystal display panels having narrow bezels have become a mainstream trend in the industry. However, with increases of panel sizes and resolutions, a load for GOAs has also increased. Thin film transistors in GOAs require a larger ratio of channel width to channel length (W/L). At present, increasing the channel width (W) on the plane is usually used to increase the ratio of channel width to channel length (W/L). However, this method will lead to an increase in the size of each TFT in the GOAs, which cannot satisfy requirements of narrow bezels of the liquid crystal display panels.

### SUMMARY OF INVENTION

An objective of the present disclosure is to provide a display panel, which can solve problems of increasing a channel width on the plane in current display panels to increase a ratio of channel width to channel length, which causes an increase in the size of each TFT in GOAs, and being unable to satisfy requirements of narrow bezels of liquid crystal display panels.

In order to solve the above problems, the present disclosure provides a display panel, which has a display area and a non-display area and includes: a substrate; at least one thin film transistor disposed on the substrate and in the non-display area; wherein, the at least one thin film transistor includes: a protruding structure disposed on the substrate, wherein, the protruding structure includes a first surface on one side away from the substrate, and a first side wall and a second side wall respectively extending to the substrate from two opposite ends of the first surface; and a source and drain electrode layer disposed on the protruding structure, wherein, the source and drain electrode layer includes a source electrode and a drain electrode spaced apart from each other, and both the source electrode and the drain electrode cover the first surface, the first side wall, and the second side wall of the protruding structure.

Further, a height of the protruding structure is less than 3 μm.

Further, in a cross-section perpendicular to the substrate, a shape of the protruding structure is trapezoidal.

Further, in the cross-section perpendicular to the substrate, an included angle between the first side wall of the protruding structure and a bottom side of the protruding structure adjacent to the substrate ranges from 30° to 60°; and an included angle between the second side wall of the protruding structure and the bottom side of the protruding structure adjacent to the substrate ranges from 30° to 60°.

Further, the thin film transistor further includes: a gate electrode disposed on the substrate, wherein, the protruding structure is multiplexed as the gate electrode of the thin film transistor; a gate insulating layer covering the first surface, the first side wall, and the second side wall of the protruding structure; and an active layer covering one side of the gate insulating layer away from the substrate and extending to cover the gate insulating layer on the first side wall and the second side wall of the protruding structure; wherein, the source and drain electrode layer is disposed on one side of the active layer away from the substrate or between the gate insulating layer and the active layer.

Further, the thin film transistor further includes: an active layer disposed on the substrate, wherein, the protruding structure is multiplexed as the active layer of the thin film transistor; the source and drain electrode layer disposed on one side of the active layer away from the substrate; a gate insulating layer covering one side of the source and drain electrode layer away from the substrate and extending to cover the source and drain electrode layer on the first side wall and the second side wall of the protruding structure; and a gate electrode covering one side of the gate insulating layer away from the substrate and extending to cover the gate insulating layer on the first side wall and the second side wall of the protruding structure.

Further, the display panel further includes: a black matrix layer disposed on the substrate; wherein, the protruding structure protrudes from a surface of the black matrix layer away from the substrate.

Further, a material of the protruding structure is same as a material of the black matrix layer, and the material of the black matrix layer includes one of a black photosensitive resin or an opaque metal.

Further, the source electrode is a strip-shaped source electrode, the drain electrode is a strip-shaped drain electrode, and the drain electrode and the source electrode are parallel to each other.

Further, the source electrode is a U-shaped source electrode and has a first source electrode branch and a second source electrode branch being parallel to each other and spaced apart, and a third source electrode branch connected the first source electrode branch and the second source electrode branch; and the drain electrode is a strip-shaped drain electrode, and the drain electrode is parallel to the first source electrode branch and is located between the first source electrode branch and the second source electrode branch.

Beneficial effect: in the display panel of the present disclosure, the thin film transistor in the non-display area is provided with the protruding structure, which includes the first surface on the side away from the substrate and the first side wall and the second side wall respectively extending to the substrate from two opposite ends of the first surface. The source and drain electrode layer is disposed on the protruding structure, and the source electrode and the drain electrode of the source and drain electrode layer both cover the first surface, the first side wall, and the second side wall of the protruding structure. Therefore, a channel width of the thin film transistor can be increased, thereby increasing a ratio of the channel width to a channel length of the thin film transistor, thereby increasing a current of the thin film transistor, improving a charging rate of the thin film transistor, and improving a display performance of the display panel.

By extending the source electrode and the drain electrode of the source and drain electrode layer to cover the first side wall and the second side wall of the protruding structure, the present disclosure can increase the channel width of the thin film transistor while not increasing a projection area of the thin film transistor on the substrate, thereby satisfying the requirement of narrow bezels of the display panel.

### DESCRIPTION OF DRAWINGS

The accompanying figures to be used in the description of embodiments of the present disclosure will be described in brief to more clearly illustrate the technical solutions of the embodiments. The accompanying figures described below are only part of the embodiments of the present disclosure, from which those skilled in the art can derive further figures without making any inventive efforts.

FIG. 1 is a schematic planar diagram of a display panel of the present disclosure.

FIG. 2 is a schematic structural diagram of a thin film transistor according to Embodiment 1 of the present disclosure.

FIG. 3 is a schematic diagram of a source and drain electrode layer and an active layer after expanding according to Embodiment 1 of the present disclosure.

FIG. 4 is a schematic right-side view of FIG. 3.

FIG. 5 is a schematic structural diagram of the thin film transistor according to Embodiment 2 of the present disclosure.

FIG. 6 is a schematic structural diagram of the thin film transistor according to Embodiment 3 of the present disclosure.

FIG. 7 is a schematic diagram of the source and drain electrode layer and the active layer after expanding according to Embodiment 4 of the present disclosure.

FIG. 8 is a schematic right-side view of FIG. 7.

### Elements in the drawings are designated by reference numerals listed below:

100: display panel; 101: display area;

102: non-display area;

1: substrate; 2: thin film transistor;

21: protruding structure; 22: gate electrode;

23: gate insulating layer; 24: active layer;

25: source and drain electrode layer;

211: first surface; 212: first side wall;

213: second side wall;

251: source electrode; 252: drain electrode;

2511: first source electrode branch; 2512: second source electrode branch; and

2513: third source electrode branch.

### DETAILED DESCRIPTION OF PREFERRED EMBODIMENTS

The preferred embodiments of the present disclosure are described in detail below with reference to the accompanying drawings. The specific embodiments described with reference to the attached drawings are all exemplary and are intended to illustrate and interpret the present disclosure to make the skilled in the art easier to understand how to implement the present disclosure. The disclosure herein provides many different embodiments or examples for realizing different structures of the present disclosure. They are only examples and are not intended to limit the present disclosure.

In the description of the present disclosure, it should be understood that terms such as “upper”, “lower”, “front”, “rear”, “left”, “right”, “inside”, “outside”, “side”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure.

In the accompanying drawings, wherein the identical or similar reference numerals constantly denote the identical or similar elements or elements having the identical or similar functions. In the drawings, structurally identical components are denoted by the same reference numerals, and structural or functionally similar components are denoted by like reference numerals. Moreover, a size and a thickness of each component shown in the drawings are arbitrarily shown for ease of understanding and description, and the present disclosure does not limit the size and thickness of each component.

### Embodiment 1

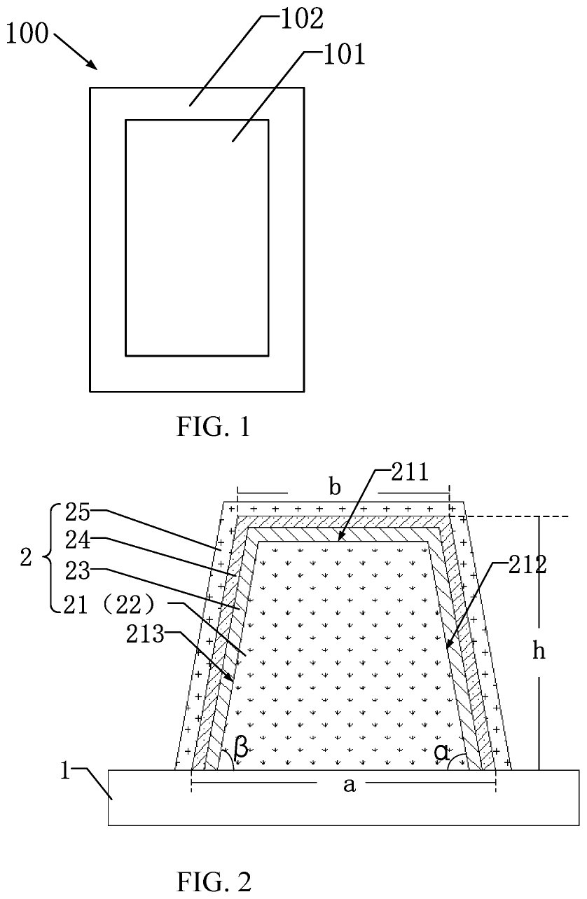

As shown in FIG. 1, this embodiment provides a display panel 100. The display panel 100 includes a display area 101 and a non-display area 102 surrounding the display area 101.

Wherein, the display panel 100 includes a substrate 1 and at least one thin film transistor 2. The at least one thin film transistor 2 is disposed on the substrate 1 and in the non-display area 102.

As shown in FIG. 2, the at least one thin film transistor 2 includes a protruding structure 21, a gate electrode 22, a gate insulating layer 23, an active layer 24, and a source and drain electrode layer 25.

As shown in FIG. 2, the protruding structure 21 is disposed on the substrate 1. The protruding structure 21 includes a first surface 211 on one side away from the substrate 1, and a first side wall 212 and a second side wall 213 respectively extending to the substrate 1 from two opposite ends of the first surface 211.

Wherein, a height of the protruding structure 21 is less than 3 μm. That is, a distance between the first surface 211 of the protruding structure 21 and a bottom side thereof adjacent to the substrate 1 is less than 3 μm. In this embodiment, the distance between the first surface 211 of the protruding structure 21 and the bottom side thereof adjacent to the substrate 1 is 1 μm. In other embodiments, the distance between the first surface 211 of the protruding structure 21 and the bottom side thereof adjacent to the substrate 1 may be 1.5 μm, 2 μm, or 2.5 μm.

In this embodiment, a shape of the protruding structure 21 is a trapezoidal platform. In a cross-section perpendicular to the substrate 1, the shape of the protruding structure 21 is trapezoidal. In the cross-section perpendicular to the substrate 1, an included angle α between the first side wall 212 of the protruding structure 21 and the bottom side of the protruding structure 21 adjacent to the substrate 1 ranges from 30° to 60°; and an included angle β between the second side wall 213 of the protruding structure 21 and the bottom side of the protruding structure 21 adjacent to the substrate 1 ranges from 30° to 60°. In this embodiment, the included angle α between the first side wall 212 of the protruding structure 21 and the bottom side of the protruding structure 21 adjacent to the substrate 1 is 45°, and the included angle β between the second side wall 213 of the protruding structure 21 and the bottom side of the protruding structure 21 adjacent to the substrate 1 is 45°. In other embodiments, the included angle α between the first side wall 212 of the protruding structure 21 and the bottom side of the protruding structure 21 adjacent to the substrate 1 may also be 35°, 40°, 50°, or 55°, and the included angle β between the second side wall 213 of the protruding structure 21 and the bottom side of the protruding structure 21 adjacent to the substrate 1 may also be 35°, 40°, 50°, or 55°.

A material of the gate electrode 22 may be molybdenum, a combination structure of molybdenum and aluminum, a combination structure of molybdenum and copper, a combination structure of molybdenum, copper, and indium zinc oxide, a combination structure of indium zinc oxide/copper/indium zinc oxide, a combination structure of molybdenum, copper, and indium tin oxide, a combination structure of nickel/copper/nickel, a combination structure of nickel-chromium/copper/nickel-chromium, or copper-niobium. In this embodiment, the protruding structure 21 is multiplexed as the gate electrode 22 of the thin film transistor 2. Therefore, the protruding structure 21 and the gate electrode 22 can be formed in a same process step, thereby simplifying the manufacturing process and saving the production cost. In other embodiments, the protruding structure 21 may also not be multiplexed as the gate electrode 22.

Wherein, the gate insulating layer 23 covers the first surface 211, the first side wall 212, and the second side wall 213 of the protruding structure 21. In this embodiment, the gate insulating layer 23 is mainly used to prevent the gate electrode 22 from being in contact with the active layer 24 to cause short circuits. A material of the gate insulating layer 23 may be silicon oxide, silicon nitride, aluminum oxide, a combination structure of silicon nitride and silicon oxide, or a combination structure of silicon oxide/silicon nitride/silicon oxide. In this embodiment, the material of the gate insulating layer 23 is silicon oxide.

Wherein, the active layer 24 covers one side of the gate insulating layer 23 away from the substrate 1 and extending to cover the gate insulating layer 23 on the first side wall 212 and the second side wall 213 of the protruding structure 21. In this embodiment, a material of the active layer 24 is low temperature polysilicon. In other embodiments, the material of the active layer 24 may also be amorphous silicon or metal oxides such as indium gallium zinc oxide (IGZO).

Wherein, the source and drain electrode layer 25 is disposed on the active layer 24. The source and drain electrode layer 25 includes a source electrode 251 and a drain electrode 252 that are spaced apart from each other in a same layer, and both the source electrode 251 and the drain electrode 252 cover the first surface 211, the first side wall 212, and the second side wall 213 of the protruding structure 21. In other words, the both the source electrode 251 and the drain electrode 252 cover one side of the active layer 24 away from the substrate 1 and extending to cover the active layer 24 on the first side wall 212 and the second side wall 213 of the protruding structure 21. Both the source electrode 251 and the drain electrode 252 are electrically connected to the active layer 24. A material of the source and drain electrode layer 25 may be molybdenum, a combination structure of molybdenum and aluminum, a combination structure of molybdenum and copper, a combination structure of molybdenum, copper, and indium zinc oxide, a combination structure of indium zinc oxide/copper/indium zinc oxide, a combination structure of molybdenum, copper, and indium tin oxide, a combination structure of nickel/copper/nickel, a combination structure of nickel-chromium/copper/nickel-chromium, or copper-niobium. That is, the thin film transistor in this embodiment is a bottom gate/top contact structure. In other embodiments, the thin film transistor may also be a bottom gate/bottom contact structure. That is, the source and drain electrode layer 25 is disposed between the gate insulating layer 23 and the active layer 24 and extends to cover the gate insulating layer 23 on the two opposite side walls of the protruding structure 21.

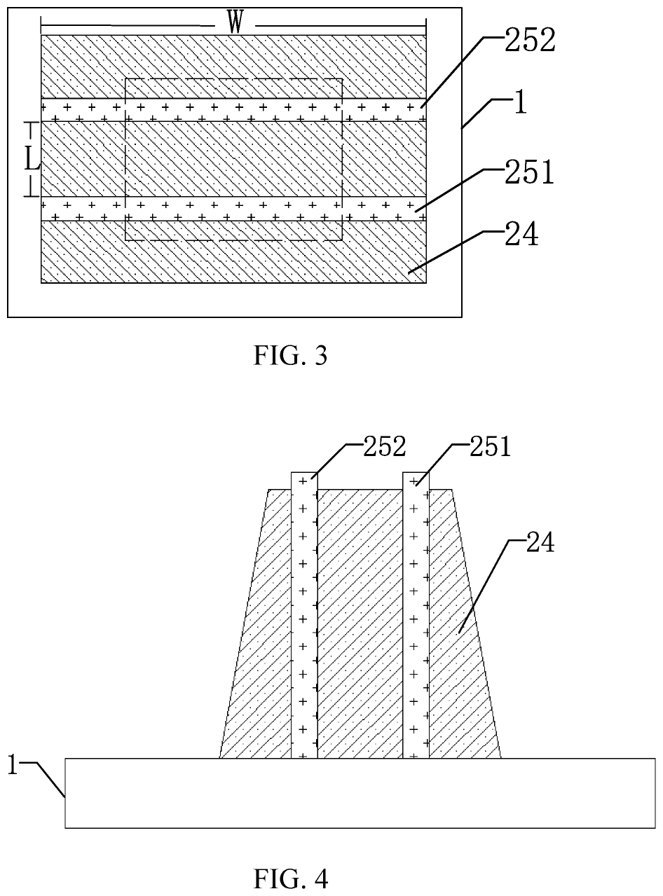

As shown in FIGS. 3 and 4, the source electrode 251 is a strip-shaped source electrode, the drain electrode 252 is a strip-shaped drain electrode, and the drain electrode 252 and the source electrode 251 are parallel to each other.

In conjunction with FIGS. 2 and 3, in this embodiment, a formula of a ratio of a channel width W to a channel length L of the thin film transistor 2 is

$$\frac{W}{L} = \frac{b + \sqrt{{( a - b )}^{2} + 4 {h}^{2}}}{L} .$$

In the display panel 100 of this embodiment, the thin film transistor 2 in the non-display area 102 is provided with the protruding structure 21, which includes the first surface 211 on the side away from the substrate 1 and the first side wall 212 and the second side wall 213 respectively extending to the substrate 1 from two opposite ends of the first surface 211. The source and drain electrode layer 21 is disposed on the protruding structure, and the source electrode 251 and the drain electrode 252 of the source and drain electrode layer 25 both cover the first surface 211, the first side wall 212, and the second side wall 213 of the protruding structure 21. Therefore, the channel width W of the thin film transistor 2 can be increased, thereby increasing the ratio of the channel width W to a channel length L of the thin film transistor 2, thereby increasing a current of the thin film transistor 2, improving a charging rate of the thin film transistor 2, and improving a display performance of the display panel 100.

By extending the source electrode 251 and the drain electrode 252 of the source and drain electrode layer 25 to cover the first side wall 212 and the second side wall 213 of the protruding structure 21, this embodiment can increase the channel width W of the thin film transistor 2 while not increasing a projection area of the thin film transistor 2 on the substrate 1, thereby satisfying the requirement of narrow bezels of the display panel 100.

### Embodiment 2

As shown in FIG. 1, this embodiment provides a display panel 100. The display panel 100 includes a display area 101 and a non-display area 102 surrounding the display area 101.

Wherein, the display panel 100 includes a substrate 1 and at least one thin film transistor 2. The at least one thin film transistor 2 is disposed on the substrate 1 and in the non-display area 102.

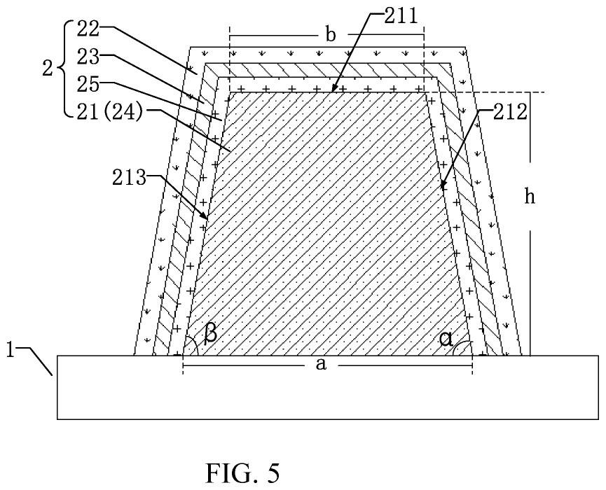

As shown in FIG. 5, the at least one thin film transistor 2 includes a protruding structure 21, a gate electrode 22, a gate insulating layer 23, an active layer 24, and a source and drain electrode layer 25.

As shown in FIG. 5, the protruding structure 21 is disposed on the substrate 1. The protruding structure 21 includes a first surface 211 on one side away from the substrate 1, and a first side wall 212 and a second side wall 213 respectively extending to the substrate 1 from two opposite ends of the first surface 211.

Wherein, a height of the protruding structure 21 is less than 3 μm. That is, a distance between the first surface 211 of the protruding structure 21 and a bottom side thereof adjacent to the substrate 1 is less than 3 μm. In this embodiment, the distance between the first surface 211 of the protruding structure 21 and the bottom side thereof adjacent to the substrate 1 is 1 μm. In other embodiments, the distance between the first surface 211 of the protruding structure 21 and the bottom side thereof adjacent to the substrate 1 may be 1.5 μm, 2 μm, or 2.5 μm.

In this embodiment, a shape of the protruding structure 21 is a trapezoidal platform. In a cross-section perpendicular to the substrate 1, the shape of the protruding structure 21 is trapezoidal. In the cross-section perpendicular to the substrate 1, an included angle α between the first side wall 212 of the protruding structure 21 and the bottom side of the protruding structure 21 adjacent to the substrate 1 ranges from 30° to 60°; and an included angle β between the second side wall 213 of the protruding structure 21 and the bottom side of the protruding structure 21 adjacent to the substrate 1 ranges from 30° to 60°. In this embodiment, the included angle α between the first side wall 212 of the protruding structure 21 and the bottom side of the protruding structure 21 adjacent to the substrate 1 is 45°, and the included angle β between the second side wall 213 of the protruding structure 21 and the bottom side of the protruding structure 21 adjacent to the substrate 1 is 45°. In other embodiments, the included angle α between the first side wall 212 of the protruding structure 21 and the bottom side of the protruding structure 21 adjacent to the substrate 1 may also be 35°, 40°, 50°, or 55°, and the included angle β between the second side wall 213 of the protruding structure 21 and the bottom side of the protruding structure 21 adjacent to the substrate 1 may also be 35°, 40°, 50°, or 55°.

As shown in FIG. 5, a material of the active layer 24 is low temperature polysilicon. In other embodiments, the material of the active layer 24 may also be amorphous silicon or metal oxides such as indium gallium zinc oxide (IGZO). In this embodiment, the protruding structure 21 is multiplexed as the active layer 24 of the thin film transistor 2. Therefore, the protruding structure 21 and the active layer 24 can be formed in a same process step, thereby simplifying the manufacturing process and saving the production cost. In other embodiments, the protruding structure 21 may also not be multiplexed as the active layer 24.

Wherein, the source and drain electrode layer 25 is disposed on the active layer 24. The source and drain electrode layer 25 includes a source electrode 251 and a drain electrode 252 that are spaced apart from each other in a same layer, and both the source electrode 251 and the drain electrode 252 cover the first surface 211, the first side wall 212, and the second side wall 213 of the protruding structure 21. In other words, the both the source electrode 251 and the drain electrode 252 cover one side of the active layer 24 away from the substrate 1 and extending to cover the active layer 24 on the first side wall 212 and the second side wall 213 of the protruding structure 21. Both the source electrode 251 and the drain electrode 252 are electrically connected to the active layer 24. A material of the source and drain electrode layer 25 may be molybdenum, a combination structure of molybdenum and aluminum, a combination structure of molybdenum and copper, a combination structure of molybdenum, copper, and indium zinc oxide, a combination structure of indium zinc oxide/copper/indium zinc oxide, a combination structure of molybdenum, copper, and indium tin oxide, a combination structure of nickel/copper/nickel, a combination structure of nickel-chromium/copper/nickel-chromium, or copper-niobium. That is, the thin film transistor in this embodiment is a top gate/top contact structure. In other embodiments, the protruding structure 21 may also not be multiplexed as the active layer 24. When the protruding structure 21 is not multiplexed as the active layer 24, the thin film transistor may also be a top gate/bottom contact structure.

As shown in FIGS. 3 and 4, the source electrode 251 is a strip-shaped source electrode, the drain electrode 252 is a strip-shaped drain electrode, and the drain electrode 252 and the source electrode 251 are parallel to each other.

In conjunction with FIGS. 5 and 3, in this embodiment, a formula of a ratio of a channel width W to a channel length L of the thin film transistor 2 is

$$\frac{W}{L} = \frac{b + \sqrt{{( a - b )}^{2} + 4 {h}^{2}}}{L} .$$

In the display panel 100 of this embodiment, the thin film transistor 2 in the non-display area 102 is provided with the protruding structure 21, which includes the first surface 211 on the side away from the substrate 1 and the first side wall 212 and the second side wall 213 respectively extending to the substrate 1 from two opposite ends of the first surface 211. The source and drain electrode layer 21 is disposed on the protruding structure, and the source electrode 251 and the drain electrode 252 of the source and drain electrode layer 25 both cover the first surface 211, the first side wall 212, and the second side wall 213 of the protruding structure 21. Therefore, the channel width W of the thin film transistor 2 can be increased, thereby increasing the ratio of the channel width W to a channel length L of the thin film transistor 2, thereby increasing a current of the thin film transistor 2, improving a charging rate of the thin film transistor 2, and improving a display performance of the display panel 100.

By extending the source electrode 251 and the drain electrode 252 of the source and drain electrode layer 25 to cover the first side wall 212 and the second side wall 213 of the protruding structure 21, this embodiment can increase the channel width W of the thin film transistor 2 while not increasing a projection area of the thin film transistor 2 on the substrate 1, thereby satisfying the requirement of narrow bezels of the display panel 100.

Wherein, the gate insulating layer 23 covers one side of the source and drain electrode layer 25 away from the substrate 1 and extending to cover the source and drain electrode layer 25 on the first side wall 212 and the second side wall 213 of the protruding structure 21. In this embodiment, the gate insulating layer 23 is mainly used to prevent the gate electrode 22 from being in contact with the source and drain electrode layer 25 to cause short circuits. A material of the gate insulating layer 23 may be silicon oxide, silicon nitride, aluminum oxide, a combination structure of silicon nitride and silicon oxide, or a combination structure of silicon oxide/silicon nitride/silicon oxide. In this embodiment, the material of the gate insulating layer 23 is silicon oxide.

Wherein, the gate electrode 22 covers one side of the gate insulating layer 23 away from the substrate 1 and extending to cover the gate insulating layer 23 on the first side wall 212 and the second side wall 213 of the protruding structure 21. A material of the gate electrode 22 may be molybdenum, a combination structure of molybdenum and aluminum, a combination structure of molybdenum and copper, a combination structure of molybdenum, copper, and indium zinc oxide, a combination structure of indium zinc oxide/copper/indium zinc oxide, a combination structure of molybdenum, copper, and indium tin oxide, a combination structure of nickel/copper/nickel, a combination structure of nickel-chromium/copper/nickel-chromium, or copper-niobium.

### Embodiment 3

As shown in FIG. 1, this embodiment provides a display panel 100. The display panel 100 includes a display area 101 and a non-display area 102 surrounding the display area 101.

Wherein, the display panel 100 includes a substrate 1 and at least one thin film transistor 2. The at least one thin film transistor 2 is disposed on the substrate 1 and in the non-display area 102.

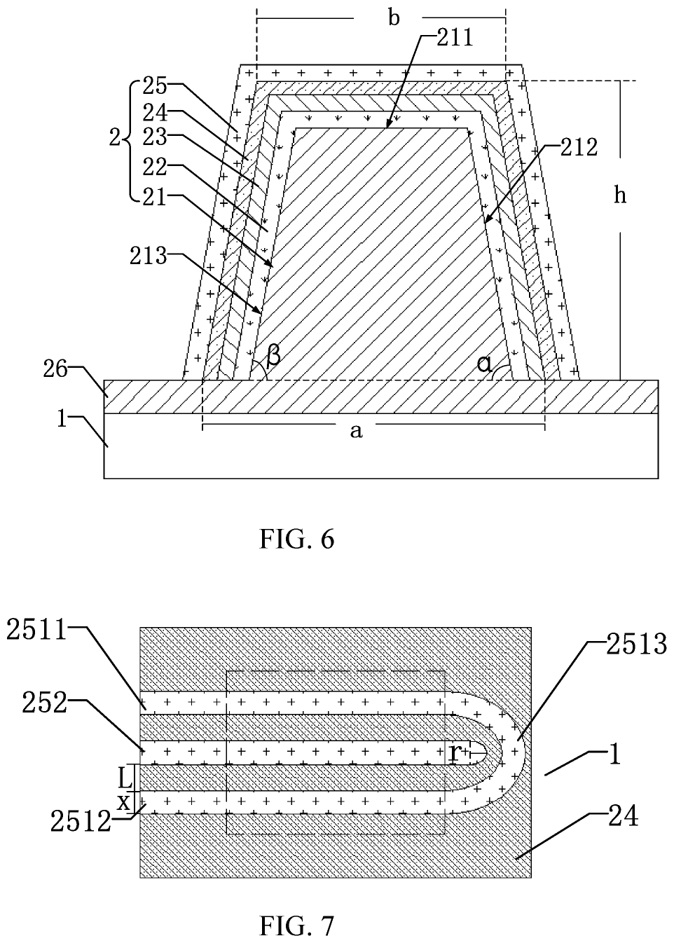

As shown in FIG. 6, the at least one thin film transistor 2 includes a protruding structure 21, a gate electrode 22, a gate insulating layer 23, an active layer 24, a source and drain electrode layer 25, and a black matrix layer 26.

As shown in FIG. 6, the black matrix layer 26 is disposed on the substrate 1. A material of the black matrix layer 26 includes one of a black photosensitive resin or an opaque metal. In this embodiment, the material of the black matrix layer 26 is chromium.

Wherein, the protruding structure 21 protrudes from a surface of the black matrix layer 26 away from the substrate 1. In this embodiment, a material of the protruding structure 21 is same as the material of the black matrix layer 26. Therefore, the protruding structure 21 and the black matrix layer 26 can be formed in a same process step, thereby simplifying the manufacturing process and saving the production cost. In other embodiments, the material of the protruding structure 21 may also be different from the material of the black matrix layer 26.

Wherein, the protruding structure 21 includes a first surface 211 on one side away from the substrate 1, and a first side wall 212 and a second side wall 213 respectively extending to the substrate 1 from two opposite ends of the first surface 211.

Wherein, a height of the protruding structure 21 is less than 3 μm. That is, a distance between the first surface 211 of the protruding structure 21 and a bottom side thereof adjacent to the substrate 1 is less than 3 μm. In this embodiment, the distance between the first surface 211 of the protruding structure 21 and the bottom side thereof adjacent to the substrate 1 is 1 μm. In other embodiments, the distance between the first surface 211 of the protruding structure 21 and the bottom side thereof adjacent to the substrate 1 may be 1.5 μm, 2 μm, or 2.5 μm.

In this embodiment, a shape of the protruding structure 21 is a trapezoidal platform. In a cross-section perpendicular to the substrate 1, the shape of the protruding structure 21 is trapezoidal. In the cross-section perpendicular to the substrate 1, an included angle α between the first side wall 212 of the protruding structure 21 and the bottom side of the protruding structure 21 adjacent to the substrate 1 ranges from 30° to 60°; and an included angle β between the second side wall 213 of the protruding structure 21 and the bottom side of the protruding structure 21 adjacent to the substrate 1 ranges from 30° to 60°. In this embodiment, the included angle α between the first side wall 212 of the protruding structure 21 and the bottom side of the protruding structure 21 adjacent to the substrate 1 is 45°, and the included angle β between the second side wall 213 of the protruding structure 21 and the bottom side of the protruding structure 21 adjacent to the substrate 1 is 45°. In other embodiments, the included angle α between the first side wall 212 of the protruding structure 21 and the bottom side of the protruding structure 21 adjacent to the substrate 1 may also be 35°, 40°, 50°, or 55°, and the included angle β between the second side wall 213 of the protruding structure 21 and the bottom side of the protruding structure 21 adjacent to the substrate 1 may also be 35°, 40°, 50°, or 55°.

As shown in FIG. 6, in this embodiment, the thin film transistor is a bottom gate/top contact structure. In other embodiments, the thin film transistor may also be a bottom gate/bottom contact structure, a top gate/bottom contact structure, or a top gate/top contact structure.

Wherein, the gate electrode 22 attaches to and covers one surface of the protruding structure 21 away from the substrate 1, and attaches to and covers the side walls of the protruding structure 21. A material of the gate electrode 22 may be molybdenum, a combination structure of molybdenum and aluminum, a combination structure of molybdenum and copper, a combination structure of molybdenum, copper, and indium zinc oxide, a combination structure of indium zinc oxide/copper/indium zinc oxide, a combination structure of molybdenum, copper, and indium tin oxide, a combination structure of nickel/copper/nickel, a combination structure of nickel-chromium/copper/nickel-chromium, or copper-niobium.

Wherein, the gate insulating layer 23 covers the first surface 211, the first side wall 212, and the second side wall 213 of the protruding structure 21. In this embodiment, the gate insulating layer 23 is mainly used to prevent the gate electrode 22 from being in contact with the active layer 24 to cause short circuits. A material of the gate insulating layer 23 may be silicon oxide, silicon nitride, aluminum oxide, a combination structure of silicon nitride and silicon oxide, or a combination structure of silicon oxide/silicon nitride/silicon oxide. In this embodiment, the material of the gate insulating layer 23 is silicon oxide.

Wherein, the active layer 24 covers one side of the gate insulating layer 23 away from the substrate 1 and extending to cover the gate insulating layer 23 on the side walls of the protruding structure 21. In this embodiment, a material of the active layer 24 is low temperature polysilicon. In other embodiments, the material of the active layer 24 may also be amorphous silicon or metal oxides such as indium gallium zinc oxide (IGZO).

Wherein, the source and drain electrode layer 25 is disposed on the active layer 24. The source and drain electrode layer 25 includes a source electrode 251 and a drain electrode 252 that are spaced apart from each other in a same layer, and both the source electrode 251 and the drain electrode 252 cover the first surface 211, the first side wall 212, and the second side wall 213 of the protruding structure 21. In other words, the both the source electrode 251 and the drain electrode 252 cover one side of the active layer 24 away from the substrate 1 and extending to cover the active layer 24 on the first side wall 212 and the second side wall 213 of the protruding structure 21. Both the source electrode 251 and the drain electrode 252 are electrically connected to the active layer 24. A material of the source and drain electrode layer 25 may be molybdenum, a combination structure of molybdenum and aluminum, a combination structure of molybdenum and copper, a combination structure of molybdenum, copper, and indium zinc oxide, a combination structure of indium zinc oxide/copper/indium zinc oxide, a combination structure of molybdenum, copper, and indium tin oxide, a combination structure of nickel/copper/nickel, a combination structure of nickel-chromium/copper/nickel-chromium, or copper-niobium.

As shown in FIGS. 3 and 4, the source electrode 251 is a strip-shaped source electrode, the drain electrode 252 is a strip-shaped drain electrode, and the drain electrode 252 and the source electrode 251 are parallel to each other.

In conjunction with FIGS. 6 and 3, in this embodiment, a formula of a ratio of a channel width W to a channel length L of the thin film transistor 2 is

$$\frac{W}{L} = \frac{b + \sqrt{{( a - b )}^{2} + 4 {h}^{2}}}{L} .$$

In the display panel 100 of this embodiment, the thin film transistor 2 in the non-display area 102 is provided with the protruding structure 21, which includes the first surface 211 on the side away from the substrate 1 and the first side wall 212 and the second side wall 213 respectively extending to the substrate 1 from two opposite ends of the first surface 211. The source and drain electrode layer 21 is disposed on the protruding structure, and the source electrode 251 and the drain electrode 252 of the source and drain electrode layer 25 both cover the first surface 211, the first side wall 212, and the second side wall 213 of the protruding structure 21. Therefore, the channel width W of the thin film transistor 2 can be increased, thereby increasing the ratio of the channel width W to a channel length L of the thin film transistor 2, thereby increasing a current of the thin film transistor 2, improving a charging rate of the thin film transistor 2, and improving a display performance of the display panel 100.

By extending the source electrode 251 and the drain electrode 252 of the source and drain electrode layer 25 to cover the first side wall 212 and the second side wall 213 of the protruding structure 21, this embodiment can increase the channel width W of the thin film transistor 2 while not increasing a projection area of the thin film transistor 2 on the substrate 1, thereby satisfying the requirement of narrow bezels of the display panel 100.

In this embodiment, the source and drain electrode layer 25 is disposed on one side of the active layer 24 away from the substrate 1, that is, the top contact. In other embodiments, the source and drain electrode layer 25 may also be disposed on one side of the active layer 24 adjacent to the substrate 1, that is, the bottom contact.

### Embodiment 4

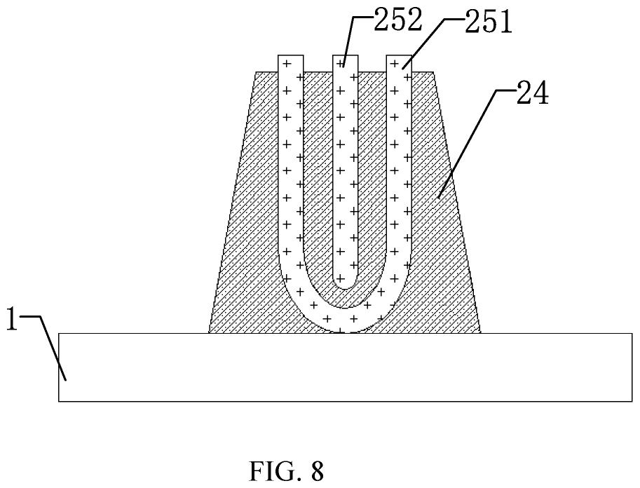

As shown in FIGS. 7 and 8, this embodiment includes most technical features of Embodiments 1 to 3. A difference between this embodiment and Embodiments 1 to 3 is that the source electrode 251 of Embodiment 4 is a U-shaped source electrode and has a first source electrode branch 2511 and a second source electrode branch 2512 being parallel to each other and spaced apart, and a third source electrode branch 2513 connected the first source electrode branch 2511 and the second source electrode branch 2512. The drain electrode 252 is a strip-shaped drain electrode, and the drain electrode 252 is parallel to the first source electrode branch 2511 and is located between the first source electrode branch 2511 and the second source electrode branch 2512.

In conjunction with FIGS. 6 and 7, in this embodiment, a formula of the ratio of the channel width W to the channel length L of the thin film transistor 2 is

$$\frac{W}{L} = \frac{π}{ln [ \frac{π ( L + r ) + ( 2 ( b - x - L + \sqrt{{( a - b )}^{2} + 4 {h}^{2} )}}{π r + 2 ( b - x - L + \sqrt{{( a - b )}^{2} + 4 {h}^{2} )}} ]} .$$

In the display panel 100 of this embodiment, the thin film transistor 2 in the non-display area 102 is provided with the protruding structure 21, which includes the first surface 211 on the side away from the substrate 1 and the first side wall 212 and the second side wall 213 respectively extending to the substrate 1 from two opposite ends of the first surface 211. The source and drain electrode layer 21 is disposed on the protruding structure, and the source electrode 251 and the drain electrode 252 of the source and drain electrode layer 25 both cover the first surface 211, the first side wall 212, and the second side wall 213 of the protruding structure 21. Therefore, the channel width W of the thin film transistor 2 can be increased, thereby increasing the ratio of the channel width W to a channel length L of the thin film transistor 2, thereby increasing a current of the thin film transistor 2, improving a charging rate of the thin film transistor 2, and improving a display performance of the display panel 100.

By extending the source electrode 251 and the drain electrode 252 of the source and drain electrode layer 25 to cover the first side wall 212 and the second side wall 213 of the protruding structure 21, this embodiment can increase the channel width W of the thin film transistor 2 while not increasing a projection area of the thin film transistor 2 on the substrate 1, thereby satisfying the requirement of narrow bezels of the display panel 100.

Further, the display panel provided in the present disclosure is described in detail above. Specific examples are used herein to explain the principles and implementation of the present disclosure. The descriptions of the above embodiments are only used to help understand the method of the present disclosure and its core ideas; meanwhile, for those skilled in the art, the range of specific implementation and application may be changed according to the ideas of the present disclosure. In summary, the content of the specification should not be construed as causing limitations to the present disclosure.

What is claimed is:

1. A display panel, having a display area and a non-display area surrounding the display area and comprising:
a substrate; and
at least one thin film transistor disposed on the substrate and in the non-display area;
wherein the at least one thin film transistor comprises:
a protruding structure disposed on the substrate, wherein the protruding structure comprises a first surface on one side away from the substrate, and a first side wall and a second side wall respectively extending to the substrate from two opposite ends of the first surface; and
a source and drain electrode layer disposed on the protruding structure, wherein the source and drain electrode layer comprises a source electrode and a drain electrode spaced apart from each other, and both the source electrode and the drain electrode cover the first surface, the first side wall, and the second side wall of the protruding structure.

2. The display panel according to claim 1, wherein a height of the protruding structure is less than 3 μm.

3. The display panel according to claim 1, wherein in a cross-section perpendicular to the substrate, a shape of the protruding structure is trapezoidal.

4. The display panel according to claim 3, wherein in the cross-section perpendicular to the substrate, an included angle between the first side wall of the protruding structure and a bottom side of the protruding structure adjacent to the substrate ranges from 30° to 60°.

5. The display panel according to claim 4, wherein in the cross-section perpendicular to the substrate, an included angle between the second side wall of the protruding structure and the bottom side of the protruding structure adjacent to the substrate ranges from 30° to 60°.

6. The display panel according to claim 5, wherein in the cross-section perpendicular to the substrate, the included angles between the first side wall of the protruding structure and the bottom side of the protruding structure adjacent to the substrate and between the second side wall of the protruding structure and the bottom side of the protruding structure adjacent to the substrate are equal.

7. The display panel according to claim 1, wherein materials of the source electrode and the drain electrode comprise one or more of molybdenum, aluminum, copper, nickel, chromium, indium zinc oxide, or indium tin oxide.

8. The display panel according to claim 1, wherein the thin film transistor further comprises:
a gate electrode disposed on the substrate, wherein the protruding structure is multiplexed as the gate electrode of the thin film transistor;
a gate insulating layer covering the first surface, the first side wall, and the second side wall of the protruding structure; and
an active layer covering one side of the gate insulating layer away from the substrate and extending to cover the gate insulating layer on the first side wall and the second side wall of the protruding structure.

9. The display panel according to claim 8, wherein the source and drain electrode layer is disposed on one side of the active layer away from the substrate.

10. The display panel according to claim 8, wherein the source and drain electrode layer is disposed between the gate insulating layer and the active layer.

11. The display panel according to claim 8, wherein a material of the gate electrode comprises one or more of molybdenum, aluminum, copper, nickel, chromium, indium zinc oxide, or indium tin oxide.

12. The display panel according to claim 8, wherein a material of the gate insulating layer comprises one or more of silicon oxide, silicon nitride, or aluminum oxide.

13. The display panel according to claim 1, wherein the thin film transistor further comprises:
an active layer disposed on the substrate, wherein the protruding structure is multiplexed as the active layer of the thin film transistor;
the source and drain electrode layer disposed on one side of the active layer away from the substrate;
a gate insulating layer covering one side of the source and drain electrode layer away from the substrate and extending to cover the source and drain electrode layer on the first side wall and the second side wall of the protruding structure; and
a gate electrode covering one side of the gate insulating layer away from the substrate and extending to cover the gate insulating layer on the first side wall and the second side wall of the protruding structure.

14. The display panel according to claim 13, wherein a material of the gate electrode comprises one or more of molybdenum, aluminum, copper, nickel, chromium, indium zinc oxide, or indium tin oxide.

15. The display panel according to claim 13, wherein a material of the gate insulating layer comprises one or more of silicon oxide, silicon nitride, or aluminum oxide.

16. The display panel according to claim 1, further comprising:
a black matrix layer disposed on the substrate;
wherein the protruding structure protrudes from a surface of the black matrix layer away from the substrate.

17. The display panel according to claim 16, wherein a material of the protruding structure is same as a material of the black matrix layer.

18. The display panel according to claim 16, wherein a material of the black matrix layer comprises one of a black photosensitive resin or an opaque metal.

19. The display panel according to claim 1, wherein the source electrode is a strip-shaped source electrode, the drain electrode is a strip-shaped drain electrode, and the drain electrode and the source electrode are parallel to each other.

20. The display panel according to claim 1, wherein the source electrode is a U-shaped source electrode and has a first source electrode branch and a second source electrode branch being parallel to each other and spaced apart, and a third source electrode branch connected the first source electrode branch and the second source electrode branch; and the drain electrode is a strip-shaped drain electrode, and the drain electrode is parallel to the first source electrode branch and is located between the first source electrode branch and the second source electrode branch.
